(19) United States
(12) Patent Application Publication
(10) Pub. No.: US 2022/0252531 A1
(43) Pub. Date: Aug. 11, 2022

(54) INFORMATION PROCESSING APPARATUS AND CONTROL METHOD FOR INFORMATION PROCESSING APPARATUS

(71) Applicant: CANON KABUSHIKI KAISHA, Tokyo (JP)

(72) Inventors: Akihiro Taya, Kanagawa (JP); Yutaka Yoshimasa, Kanagawa (JP); Hidetaka Kawamura, Kanagawa (JP)

(21) Appl. No.: 17/732,314

(22) Filed: Apr. 28, 2022

Related U.S. Application Data
(63) Continuation of application No. PCT/JP2020/040743, filed on Oct. 30, 2020.

(30) Foreign Application Priority Data
Nov. 1, 2019 (JP) 2019-200321

(51) Int. Cl. G01N 23/2258

(52) U.S. Cl. CPC G01N 23/2258; G01N 2223/507; G01N 2223/506

(57) ABSTRACT

An information processing apparatus includes information acquisition means configured to acquire quantitative information on a test substance, which is estimated by inputting spectrum information of a sample including the test substance into a learning model, and degree-of-contribution acquisition means configured to acquire a degree of contribution of the acquired quantitative information on the test substance.

### CROSS-REFERENCE TO RELATED APPLICATIONS

This application is a Continuation of International Patent Application No. PCT/JP2020/040743, filed Oct. 30, 2020, which claims the benefit of Japanese Patent Application No. 2019-200321, filed Nov. 1, 2019, both of which are hereby incorporated by reference herein in their entirety.

### TECHNICAL FIELD

The present invention relates to an information processing apparatus and a control method for the information processing apparatus.

### BACKGROUND ART

Spectrum analysis is widely used as a method for detecting a concentration and/or an amount of a specific component (hereinafter referred to as a test substance) contained in various samples. In spectrum analysis, some stimulus is applied to a sample, and a response of the sample to the stimulus is detected. Based on an obtained response signal, information about components of the sample (spectrum information) can be obtained. The spectrum information is information that characterizes the stimulus and/or the response. Examples of the spectrum information include, in addition to the intensity of electromagnetic waves including light, information regarding temperature, mass, and the count of particles each having a particular mass. In another example of spectrum analysis, electron impact is used as a stimulus and the amount of particles generated by decomposition by the electron impact is recorded for various masses of the particles thereby obtaining information about a structure or the like. More specifically, examples of spectrum analysis includes visible/ultraviolet absorption spectrum (UV/Vis spectrum) analysis, infrared absorption spectrum (IR spectrum) analysis, nuclear magnetic resonance spectrum (NMR spectrum) analysis, Raman spectrum analysis, fluorescence spectrum analysis, atomic absorption analysis, frame analysis, emission spectroscopy, X-ray analysis, X-ray diffraction analysis, fluorescent X-ray diffraction analysis, paramagnetic resonance absorption spectrum analysis, mass spectrum analysis, thermal analysis, capillary electrophoresis analysis, etc.

In another example of a spectrum analysis method, separation of constituents is tried using differences in steric size, electric charge, and hydrophilic/hydrophobic properties among the constituents, and then the constituents are analyzed by irradiating them with an electromagnetic wave. This is called separation analysis. For example, in liquid chromatography (hereinafter referred to as HPLC), a test substance and other substances (hereinafter referred to as impurities) are separated by optimizing analysis conditions in terms of column species, mobile phase species, temperature, flow velocities, etc. Thereafter, the spectrum of the separated test substance is measured thereby detecting the concentration and/or the amount thereof.

Another example is secondary ion mass spectrometry such as time-of-flight secondary ion mass spectrometry (TOF-SIMS) in which a solid sample is irradiated with an ion beam to obtain information on elements and molecules present on the surface of the solid sample. When the ion beam (a primary ion) is applied to the solid sample in a high vacuum, constituents on the surface of the solid sample are released into the vacuum. Positively or negatively charged ions (secondary ions) generated in this process are converged in one direction by an electric field and detected at a position separated by a certain distance. Secondary ions with various masses are generated depending on the composition of the surface of the solid sample. In a constant electric field, ions with a smaller mass fly faster and ions with a larger mass fly slower. Therefore, masses of the generated secondary ions can be analyzed by measuring times (flight times) from the generation of the secondary ions to the arrival at a detector.

However, the spectrum analysis method requires knowledge and skills to read values of spectra. For example, in the HPLC, it is necessary that the spectrum information is separated sufficiently between a test substance and other impurities, and a separation procedure technique and a preprocessing technique are required. In the TOF-SIMS method, impurities are also detected at the same time when the test substance is detected, and thus knowledge and experience are required to determine which parts of the spectrum information are related to the test substance.

In recent years, with the development of machine learning methods using deep learning, machine learning has been introduced into analysis methods. In PTL 1, a determination as to whether or not a person is suffering from a disease is made using deep learning based on mass spectrum information obtained using a mass spectrometer.

### CITATION LIST

### Patent Literature

PTL 1: Japanese Patent Laid-Open No. 2018-152000

The machine learning method using deep learning is a method that can realize spectrum analysis in a simple and highly accurate manner without knowledge and skills which are required in conventional techniques. However, data processing in deep learning is in a black box, and the basis for the calculation result is not clarified. Therefore, there is a problem that it is difficult to judge whether or not the obtained result is reliable.

### SUMMARY OF INVENTION

According to the present invention, an information processing apparatus includes information acquisition means configured to acquire quantitative information on a test substance, which is estimated by inputting spectrum information of a sample including the test substance into a learning model, and degree-of-contribution acquisition means configured to acquire a degree of contribution of the acquired quantitative information on the test substance.

According to the present invention, a method for an information processing apparatus includes an information acquisition step for acquiring quantitative information on a test substance, which is estimated by inputting spectrum information of a sample including the test substance into a learning model, and a degree-of-contribution acquisition step for acquiring a degree of contribution of the acquired quantitative information on the test substance.

Further features of the present invention will become apparent from the following description of exemplary embodiments with reference to the attached drawings.

### BRIEF DESCRIPTION OF DRAWINGS

FIG. 1 is a diagram showing an example of an overall configuration of an information processing system including an information processing apparatus according to an embodiment of the present invention.

FIG. 2 is a flowchart showing an example of a processing procedure relating to generation of a learning model according to an embodiment of the present invention.

FIG. 3 is a flowchart showing an example of a processing procedure for acquiring a degree of contribution according to an embodiment of the present invention.

FIG. 4 is a schematic block diagram of an analysis apparatus in EXAMPLE 1 according to the present invention.

FIG. 5 is a flowchart showing an embodiment of the present invention.

FIG. 6 shows an example of a display unit in HPLC.

FIG. 7A shows an example of a display unit of HPLC according to another embodiment of the present invention.

FIG. 7B shows an example of a display unit of HPLC according to another embodiment of the present invention.

FIG. 8 shows an example of a display unit in TOF-SIMS.

FIG. 9 is a diagram showing a relationship between an additive concentration and an intensity of a specific mass spectrum.

FIG. 10 is a diagram showing an example of a display unit of TOF-SIMS according to another embodiment.

FIG. 11 shows an example of a manner in which information is displayed on a display unit according to an embodiment of the invention.

FIG. 12 shows an example of a manner in which information is displayed on a display unit according to an embodiment of the invention.

FIG. 13 shows an example of a manner in which information is displayed on a display unit according to an embodiment of the invention.

FIG. 14 shows an example of a manner in which information is displayed on a display unit according to an embodiment of the invention.

FIG. 15 shows an example of a manner in which information is displayed on a display unit according to an embodiment of the invention.

FIG. 16 shows an example of a manner in which information is displayed on a display unit according to an embodiment of the invention.

FIG. 17 shows an example of a manner in which information is displayed on a display unit according to an embodiment of the invention.

FIG. 18 is a schematic diagram for explaining a learning method performed according to an embodiment of the present invention.

FIG. 19 shows an example of an output displayed on a display unit according to an embodiment of the present invention.

FIG. 20 shows an example of an output displayed on a display unit according to an embodiment of the present invention.

### DESCRIPTION OF EMBODIMENTS

First, terms are described below before embodiments of the present invention are described.

Sample

In embodiments, a sample is a mixture of a plurality of types of compounds. In the embodiments, it is assumed that the sample contains a test substance and another substance (an impurity). There is no particular restriction on the sample as long as it is a mixture of substances. Furthermore, it is not necessary that the components of the mixture are identified, and the mixture may contain an unknown component. For example, the mixture may contain a substance derived from a living body such as blood, urine, or saliva, or it may contain a substance derived from a food or drink. Since the analysis of a biogenous sample provides a clue to a nutritional and health status of a person who provides the sample, and the analysis is medically and nutritionally valuable. For example, urinary vitamin B3 is involved in metabolism of sugars, lipids and proteins, and energy production. Therefore, measurement of its urinary metabolite N1-methyl-2-pyridone-5-carboxamide helps to provide nutritional guidance for health maintenance.

Test Substance

In the embodiments, the test substance is one or more known components contained in the sample. For example, the test substance is at least one selected from the group consisting of a protein, DNA, a virus, fungi, a water-soluble vitamin, a fat-soluble vitamin, an organic acid, a fatty acid, an amino acid, a sugar, an agricultural chemical, and an environmental hormone.

For example, to detect the amount of a nutrient, the test substance may be thiamine (vitamin B1), riboflavin (vitamin B2), N1-methylnicotinamide, N1-methyl-2-pyridone-5-carboxamide, which are both a vitamin B3 metabolite, 4-pyridoxic acid which is a vitamin B6 metabolite, etc. Other examples of test substances are water-soluble vitamins such as N1-methyl-4-pyridone-3-carboxamide, a pantothenic acid (vitamin B5), pyridoxin (vitamin B6), biotin (vitamin B7), a pteroylmonoglutamic acid (vitamin B9), cyanocobalamine (vitamin B12), an ascorbic acid (vitamin C). Still other examples of test substances are amino acids such as L-tryptophan, lysine, methionine, phenylalanine, threonine, valine, leucine, isoleucine, and L-histidine. Still other examples of test substances are minerals such as sodium, potassium, calcium, magnesium and phosphorus.

Quantitative Information

In the embodiments, quantitative information refers to at least one selected from the group consisting of the amount of the test substance contained in the sample, the concentration of the test substance contained in the sample, and the presence or absence of the test substance in the sample. Another example of quantitative information is at least one selected from the group consisting of the ratio of the concentration or the amount of the test substance contained in the sample relative to a reference value, and the amount or the ratio of the concentration contained in the sample of the test substance.

Spectrum Information

In the embodiments, the spectrum information is at least one selected from the group consisting of a chromatogram, a photoelectron spectrum, an infrared absorption spectrum (an IR spectrum), a nuclear magnetic resonance spectrum (an NMR spectrum), a fluorescence spectrum, a fluorescent X-ray spectrum, an ultraviolet/visible absorption spectrum (a UV/Vis spectrum), a Raman spectrum, an atomic absorption spectrum, a flame emission spectrum, an emission spectrum, an X-ray absorption spectrum, an X-ray diffraction spectrum, a paramagnetic resonance absorption spectrum, an electron spin resonance spectrum, a mass spectrum, and a thermal analysis spectrum.

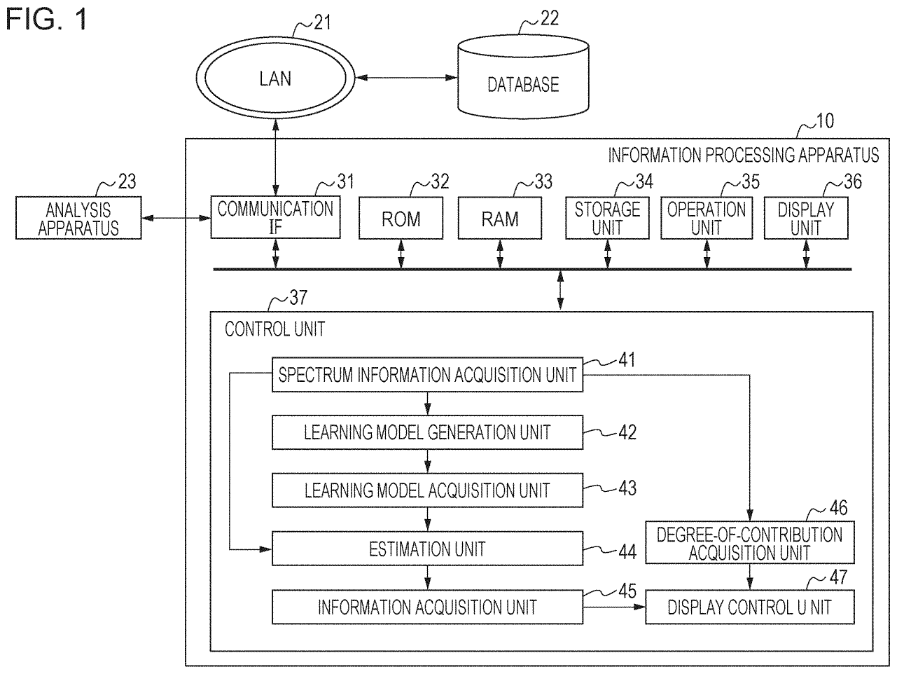

Next, an information processing system according to an embodiment is described with reference to FIG. 1. FIG. 1 is a diagram showing an overall configuration of the information processing system including an information processing apparatus according to a first embodiment.

The information processing system includes an information processing apparatus 10, a database 22, and an analysis apparatus 23. The information processing apparatus 10 and the database 22 are connected to each other so as to be capable of communicating with each other via communication means. In the present embodiment, the communication means is configured by a LAN (Local Area Network) 21. The information processing apparatus 10 and the analysis apparatus 23 are connected to each other via communication means according to a standard such as USB (Universal Serial Bus). The LAN may be a wired LAN, a wireless LAN, or a WAN. A LAN may be used instead of USB.

The database 22 manages spectrum information acquired as a result of the analysis by the analysis apparatus 23. The database 22 also manages a learning model (a trained model) generated by a learning model generation unit 42 described later. The information processing apparatus 10 acquires the spectrum information and the learning model managed by the database 22 via the LAN 21.

The learning model according to the present embodiment is a regression learning model, which may be generated by machine learning such as deep learning. The learning model referred to here is one that is constructed by training using training data according to a machine learning algorithm so as to be capable of making an appropriate prediction. There are various types of machine learning algorithms used in learning models. An example is deep learning using a neural network. The neural network includes an input layer, an output layer, and a plurality of hidden layers, wherein layers are coupled via formulae called activation functions. In a case where training data with a label (an output corresponding to an input) is used, coefficients of the activation functions are determined such that the output correctly corresponds to the input. By determining the coefficients using a plurality of pieces of training data, it is possible to generate a learning model that can predict the output for the input with high accuracy.

The analysis apparatus 23 is an apparatus for analyzing a sample, a test substance, or the like. The analysis apparatus 23 is an example of analysis means. As described above, in the present embodiment, the information processing apparatus 10 and the analysis apparatus 23 are connected to each other so as to be capable of communicating with each other. However, alternatively, the analysis apparatus 23 may be disposed inside the information processing apparatus 10, or the information processing apparatus 10 may be disposed inside the analysis apparatus 23. Still alternatively, an analysis result (spectrum information) may be transferred from the analysis apparatus 23 to the information processing apparatus 10 via a storage medium such as a non-volatile memory.

In the present embodiment, there is no particular restriction on the analysis apparatus 23 as long as it is capable of acquiring spectrum information. The analysis apparatus 23 may be an apparatus using a chemical analysis method or a physical analysis method. In the present embodiment, in the case where the analysis apparatus uses the chemical analysis method, the chemical method uses, for example, at least one selected from the group consisting of chromatography such as liquid chromatography or gas chromatography, and capillary electrophoresis. In the present embodiment, in the case where the analysis apparatus uses the physical analysis method, the physical analysis method uses, for example, at least one selected from the group consisting of photoelectron spectroscopy, infrared absorption spectroscopy, nuclear magnetic resonance spectroscopy, fluorescence spectroscopy, fluorescence X-ray spectroscopy, visible/ultraviolet absorption spectroscopy, Raman spectroscopy, atomic absorption spectroscopy, flame emission spectroscopy, emission spectroscopy, X-ray absorption spectroscopy, X-ray diffraction spectroscopy, electron spin resonance spectroscopy using normal magnetic resonance absorption, mass spectroscopy, and thermal spectroscopy. As the mass spectroscopy method, for example, time-of-flight secondary ion mass spectroscopy may be used.

For example, an analysis apparatus using liquid chromatography includes a mobile phase container, a liquid feed pump, a sample injection unit, a column, a detector, and an A/D converter. As the detector, an electromagnetic wave detector using ultraviolet rays, visible rays, infrared rays, etc., an electrochemical detector, an ion detector or the like may be used. In this case, the obtained spectrum information indicates the intensity of the output from the detector as a function of time.

The information processing apparatus 10 includes, as its functional units, a communication IF 31, a ROM 32, a RAM 33, a storage unit 34, an operation unit 35, a display unit 36, and a control unit 37.

The communication IF (Interface) 31 is realized, for example, by a LAN card and a USB interface card. The communication IF 31 performs communication between the information processing apparatus 10 and an external apparatus (for example, between the data base 22 and the analysis apparatus 23) via the LAN 21 and the USB. The ROM (Read Only Memory) 32 is realized by a non-volatile memory or the like, and serves to store various types of programs and/or the like. The RAM (Random Access Memory) 33 is realized by a volatile memory or the like, and serves to temporarily store various types of information. The storage unit 34 is realized by, for example, an HDD (Hard Disk Drive) or the like, and serves to store various types of information. The operation unit 35 is realized by, for example, a keyboard, a mouse, or the like, and serves to input an instruction given by a user into the apparatus. The display unit 36 is realized by, for example, a display or the like, and serves to display various types of information for the user. The operation unit 35 and the display unit 36 provide a function as a GUI (Graphical User Interface) under the control of the control unit 37.

The control unit 37 is realized by, for example, at least one CPU (Central Processing Unit) or the like, and serves to control processing performed in the information processing apparatus 10 in an integrated manner. The control unit 37 includes, as its functional units, a spectrum information acquisition unit 41, a learning model generation unit 42, a learning model acquisition unit 43, an estimation unit 44, an information acquisition unit 45, a degree-of-contribution acquisition unit 46, and a display control unit 47.

Here, the degree of contribution may be information indicating the degree of contribution of information included in the spectrum information in acquiring quantitative information on the test substance.

The spectrum information acquisition unit 41 acquires a result of analysis on a sample containing a test substance, and more specifically, spectrum information on the sample from the analysis apparatus 23. Note that the spectrum information on the sample may be acquired from the database 22 in which the analysis result is stored in advance. Similarly, spectrum information on the test substance is acquired. The spectrum information on the test substance refers to spectrum information obtained in a state where the test substance is alone present. Thereafter, the spectrum information acquisition unit 41 outputs the acquired spectrum information on the sample to the estimation unit 44 and the degree-of-contribution acquisition unit 46. Furthermore, the spectrum information acquisition unit 41 outputs the acquired spectrum information on the test substance to the learning model generation unit 42 and the degree-of-contribution acquisition unit 46.

Here, the spectrum information may be such spectrum information that includes information regarding a graph having a plurality of peaks wherein the height of the peaks correspond to quantitative information of substances contained in the sample, and the positions of the peaks correspond to types of the substances contained in the sample. In this case, the degree of contribution may be information indicating the degree of contribution of each of the plurality of peaks in acquiring quantitative information of the test substance.

The learning model generation unit 42 generates training data using the spectrum information of the test substance acquired by the spectrum information acquisition unit 41. The learning model generation unit 42 then executes deep learning using the training data to generate a learning model. A detailed description of the generation of training data and the generation of the learning model will be given later. The learning model generation unit 42 outputs the generated learning model to the learning model acquisition unit 43. Note that the learning model generation unit 42 may output the generated learning model to the database 22.

The learning model acquisition unit 43 acquires the learning model generated by the learning model generation unit 42. In a case where the learning model is stored in the database 22, the learning model acquisition unit 43 acquires the learning model from the database 22. The learning model acquisition unit 43 outputs the acquired learning model to the estimation unit 44.

The estimation unit 44 inputs the spectrum information of the sample acquired by the spectrum information acquisition unit 41 into the learning model acquired by the learning model acquisition unit 43, and causes the learning model to estimate the quantitative information of the test substance contained in the sample. The estimation unit 44 outputs the estimated quantitative information to the information acquisition unit 45. The estimation unit 44 is an example of estimation means configured to estimate quantitative information of a test substance by inputting spectrum information of a sample into the learning model.

The information acquisition unit 45 acquires the quantitative information estimated by the learning model. That is, the information acquisition unit 45 is an example of information acquisition means configured to acquire quantitative information of the test substance, which is estimated by inputting spectrum information of the sample containing the test substance into the learning model. The information acquisition unit 45 outputs the acquired quantitative information to the display control unit 47.

The degree-of-contribution acquisition unit 46 acquires the degree-of-contribution of the quantitative information of the test substance acquired by the information acquisition unit 45. That is, the degree-of-contribution acquisition unit 46 is an example of degree-of-contribution acquisition means configured to acquire the degree of contribution of the acquired quantitative information of the test substance. In the present embodiment, the degree of contribution indicates the degree to which each spectrum in the spectrum information of the sample has an influence to the quantitative information of the test substance estimated by the learning model. A detailed description of the acquisition of the degree of contribution will be given later. The degree-of-contribution acquisition unit 46 outputs the acquired degree of contribution to the display control unit 47.

The display control unit 47 performs control such that the quantitative information acquired by the information acquisition unit 45 and the degree of contribution acquired by the degree-of-contribution acquisition unit 46 are displayed on the display unit 36. The display control unit 47 is an example of display control means.

At least a part of the units included in the control unit 37 may be realized as an independent apparatus, or may be realized as software that realizes a function. In this case, software that realizes a function may operate on a server such as a cloud server via a network. In the present embodiment, it is assumed that each unit is realized by software in a local environment.

Note that the configuration of the information processing system shown in FIG. 1 is merely an example. For example, the storage unit 34 of the information processing apparatus 10 may have the function of the database 22, and the storage unit 34 may store various types of information.

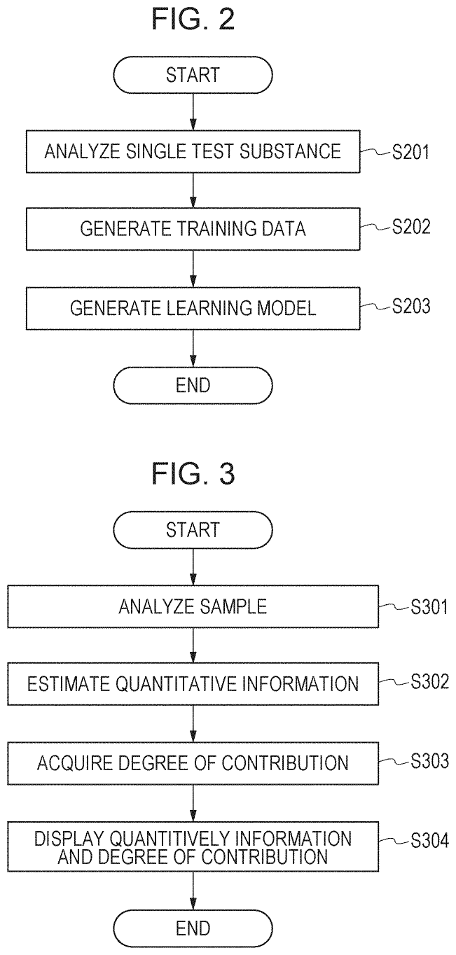

Next, a processing procedure according to the present embodiment is described with reference to FIGS. 2 and 3.

FIG. 2 is a flowchart showing a processing procedure relating to generation of a learning model.

S201 (Analyzing of Single Test Substance)

In step S201, the analysis apparatus 23 analyzes a single test substance and acquires spectrum information of the test substance. The analysis condition may be appropriately selected from viewpoints of sensitivity, analysis time, and the like. In the analysis, the analysis apparatus 23 performs the analysis for several different concentrations of the test substance. The number of concentrations depends on the property of the substance, but in general it is desirable to perform analysis for three or more different concentrations. In a case where there are a plurality of types of test substances, it is desirable to analyze each type of test substance separately. However, in a case where signals are sufficiently separated for the plurality of types of test substances, they may be analyzed together. The analysis apparatus 23 outputs the acquired spectrum information to the information processing apparatus 10. The information processing apparatus 10 receives the spectrum information from the analysis apparatus 23 and stores the received spectrum information in the RAM 33 or the storage unit 34. The spectrum information acquisition unit 41 acquires the spectrum information and stores it in the above-described manner. As described above, the spectrum information obtained as a result of the analysis may be stored in the database 22. In this case, the spectrum information acquisition unit 41 acquires the spectrum information from the database 22. The analysis apparatus 23 may analyze the test substance at any timing as long as the analysis is executed before the training data is generated in step S202.

S202 (Generating of Training Data)

In step S202, the learning model generation unit 42 generates a plurality of pieces of training data using the spectrum information of the test substance acquired by the spectrum information acquisition unit 41. A specific method of generating training data is described below. The training data is generated by adding an arbitrary waveform generated by a random number to the spectrum information of the test substance. For example, in the liquid chromatography, in many cases, spectrum information (a chromatogram) has a waveform represented by a Gaussian distribution. Therefore, the learning model generation unit 42 adds a plurality of Gaussian curves (Gaussian functions) whose peak heights, median values, and standard deviations are determined by random numbers thereby generating a plurality of random noises. Then, the learning model generation unit 42 generates a plurality of waveforms by adding each of the plurality of random noises to the waveform represented by the spectrum information of the test substance. The plurality of waveforms generated in this way are used as spectrum information (spectrum information for training) of virtual samples containing the test substance and impurities. That is, it is determined that the generated plurality of spectrum information are to be used as input data of the training data. Furthermore, the learning model generation unit 42 determines that the peak height (quantitative information) identified from the spectrum information of the test substance, on the basis of which the spectrum information was generated, is correct answer data of the training data. The learning model generation unit 42 generates the plurality of pieces of training data, each of which is a set of input data and correct answer data. Since the learning model generation unit 42 has acquired in step S201 the spectrum information for each of different concentrations of the test substance, the learning model generation unit 42 generates a plurality of pieces of training data for the respective different concentrations.

In a known technique, machine learning is performed to learn a relation between mass spectrum data of a sample and the presence/absence of cancer. However, a large amount of training data is required to achieve high accuracy in machine learning. For example, it is necessary to prepare 90,000 different pieces of data as training data. That is, although machine learning can provide complicated analysis results with high accuracy, it has a disadvantage that it is necessary to prepare a large amount of training data. In the present embodiment, it is not necessary to prepare a large amount of training data without having a difficulty that often occurs in machine learning, and thus it is possible to reduce the burden on a user.

Instead of generating the training data in the above-described manner, the training data may be generated such that a plurality of pieces of spectrum information of a plurality of samples for learning are acquired by analyzing the samples using the analysis apparatus 23, and the obtained plurality of pieces of spectrum information are combined with quantitative information of the test substance and are used as training data. Note that spectrum information of a virtual sample may be generated by a method different from the method described above.

S203 (Generating of Learning Model)

In step S203, the learning model generation unit 42 generates a learning model by performing machine learning according to a predetermined algorithm using a plurality of pieces of training data generated, in step S202, for each concentration. In the present embodiment, a neural network is used as the predetermined algorithm. By training the neural network using a plurality of pieces of training data, the learning model generation unit 42 generates a learning model that estimates, based on the input spectrum information of the sample, quantitative information of the test substance contained in the sample. The method of training the neural network is well known, and thus a further detailed description thereof is omitted in the present embodiment. As the predetermined algorithm, for example, SVM (support vector machine), DNN (deep neural network), CNN (convolutional neural network) or the like may be used. In a case where there are a plurality of types of test substances, a learning model is built for each substance. The learning model generation unit 42 stores the generated learning model in the RAM 33, the storage unit 34, or the database 22.

That is, the learning model for estimating, based on the spectrum information of the sample, quantitative information of the test substance contained in the sample is generated in the above-described manner.

Next, a method of acquiring a degree of contribution is described. FIG. 3 is a flowchart showing a processing procedure for acquiring the degree of contribution.

S301 (Analyzing of Sample)

In step S301, the analysis apparatus 23 analyzes a target sample and acquires spectrum information of the sample. The same analysis condition is used as that used in step S201 described above. The analysis apparatus 23 outputs the acquired spectrum information to the information processing apparatus 10. The information processing apparatus 10 receives the spectrum information from the analysis apparatus 23 and stores the received spectrum information in the RAM 33 or the storage unit 34. The spectrum information acquisition unit 41 acquires the spectrum information and stores it in the above-described manner. As described above, the spectrum information obtained as a result of the analysis may be stored in the database 22. In this case, the spectrum information acquisition unit 41 acquires the spectrum information from the database 22. Note that the analysis apparatus 23 may analyze the sample at any timing as long as the analysis is executed before the estimation of the quantitative information is performed in step S302.

S302 (Estimating of Quantitative Information)

In step S302, the learning model acquisition unit 43 acquires the learning model stored in the RAM 33, the storage unit 34, or the database 22. Then, the estimation unit 44 causes the acquired learning model to estimate the quantitative information of the test substance contained in the sample by inputting the spectrum information of the sample acquired in step S301 to the learning model. Furthermore, as necessary, the estimation unit 44 converts the estimated quantitative information into a format in which estimated quantitative information is to be displayed on the display unit 36. The format for being displayed on the display unit 36 may be a concentration or a ratio to a reference amount (a standard amount). In a case where the value estimated by the training model is expressed in the format for being displayed, the conversion is not necessary. The information acquisition unit 45 acquires the estimated quantitative information from the estimation unit 44 and stores it in the RAM 33 or the storage unit 34.

As described above, even when the peak of the test substance and the peak of an impurity are not completely separated, by using the learning model obtained by the machine learning, it is possible to obtain the quantitative information of the test substance with high accuracy without complicated and advanced knowledge about analysis.

Therefore, even a non-expert can easily perform quantitative analysis of the test substance with high accuracy.

S303 (Acquiring of Degree of Contribution)

In step S303, the degree-of-contribution acquisition unit 46 acquires the degree of contribution of the quantitative information estimated in step S302.

An example of embodiments of the present invention is described below with reference to the drawings, regarding a method of acquiring the degree of contribution etc. However, the scope of the present invention is not limited to the embodiments described below.

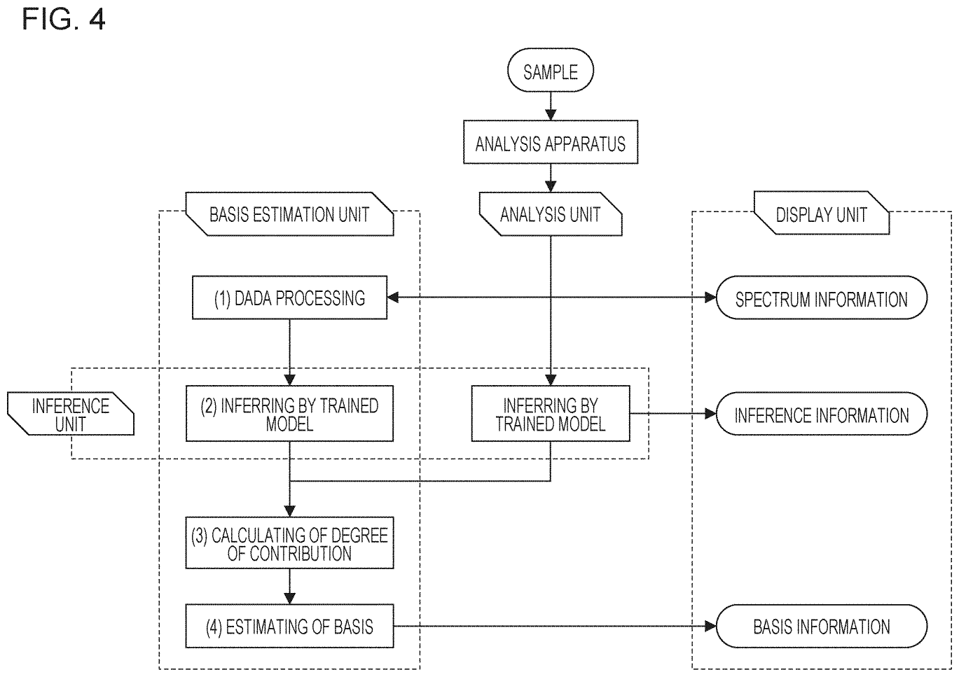

FIG. 4 is a schematic block diagram showing a processing flow of a process performed by an analysis data processing apparatus according to the present invention.

Configuration of Analysis Data Processing Apparatus

The analysis data processing apparatus includes an analysis unit configured to acquire analysis data from the analysis apparatus, an inference unit configured to infer a result from spectrum information acquired by the analysis unit, a basis estimation unit configured to estimate a basis for inference, and a display unit configured to display results thereof.

Analysis Unit

The analysis unit is one of various analyzers for obtaining the analysis result of the sample. There are various instruments used for analysis on, for example, visible/ultraviolet absorption spectrum (UV/Vis spectra), infrared absorption spectra (IR spectrum), nuclear magnetic resonance spectrum (NMR spectrum), Raman spectrum analysis, fluorescence spectrum analysis, atomic absorption analysis, flame analysis, emission spectroscopy analysis, X-ray analysis, X-ray diffraction, X-ray fluorescence diffraction, paramagnetic resonance absorption spectrum, mass spectrum analysis, thermal analysis, gas chromatography, and liquid chromatography.

For example, the liquid chromatography includes a mobile phase container, a liquid feed pump, a sample injection unit, a column, a detector, and an A/D converter. As the detector, an electromagnetic wave detector using ultraviolet rays, visible rays, infrared rays, etc., an electrochemical detector, an ion detector or the like may be used. In this case, the obtained spectrum information indicates the intensity of the output from the detector as a function of time.

Inference Unit

The inference unit calculates the amount and the type of the sample based on the spectrum information using the trained model obtained in advance by machine learning. There are various types of machine learning algorithms used in generating the learning model. An example is deep learning using a neural network. The neural network includes an input layer, an output layer, and a plurality of hidden layers, wherein layers are coupled via formulae called activation functions. In a case where training data with a label (an output corresponding to an input) is used, coefficients of the activation functions are determined such that the output correctly corresponds to the input. By determining the coefficients using a plurality of pieces of training data, it is possible to generate a learning model capable of predicting an output corresponding to an input with high accuracy.

In the present embodiment, the trained model may be generated by machine learning such as deep learning. The trained model refers to a learning model that is constructed by fitting a plurality of coefficients of the prepared learning model using training data so as to be capable of performing appropriate prediction. There are various types of learning models. For example, a learning model called a deep neural network is composed of an input layer, an output layer, and a plurality of hidden layers, wherein layers are coupled via calculation formulae called activation functions. In a case where training data with a label (an output corresponding to an input) is used, coefficients of the activation functions are determined such that the output correctly corresponds to the input. By determining the coefficients using a plurality of pieces of training data, it is possible to generate a trained model capable of predicting an output corresponding to an input with high accuracy.

Basis Estimation Unit

The basis estimation unit calculates the degree of contribution of spectrum information in inferring and estimates the basis for the inference based on the result of the calculation. According to a known method of calculating the degree of contribution in machine learning using a trained model, the degree of contribution of each dimension of an input to an output is calculated by partial differentiation. For example, the value of the spectrum information f(x) at x=α is varied by β((1) data processing in FIG. 4). The varied spectrum information is applied to the trained model ((2) inferring by trained model in FIG. 4). The change Δy in the obtained inference result is calculated, and Δy/β is employed as the degree of contribution at x=α ((3) calculating of degree of contribution in FIG. 4). The trained model used here is the same as that used in the inference unit.

In an example of a method for estimating the basis, a part of the spectrum information having a large degree of contribution is output as the basis for calculation ((4) estimating of basis in FIG. 4). For example, in the case of analysis for identifying the type of substance from a mass spectrum, a position of a peak in an output is a basis for the identification.

In another method of calculating the degree of contribution, a plurality of pieces of information in the spectrum information are varied. From the change in the output that occurs when the value of x of the spectrum information f(x) is varied at x=α₁, α₂, α₃, . . . , and αₙ, respectively, it is possible to calculate the degree of contribution of a combination of α₁, α₂, α₃, . . . , and αₙ. For example, in the mass spectrum obtained by TOF-SIMS, the magnitude of a specific peak does not necessarily change in proportion to the concentration of the sample, but in significantly many cases, the concentration of one sample is determined by a combination of a plurality of peaks. For example, in some cases, when the concentration of a sample exceeds a certain value, an increase in another peak occurs. By determining the degree of contribution for each of combinations of peaks, it is possible to estimate the basis for inferring, that is, which combination of peaks is the basis for the inference.

Display Unit

The display unit displays the spectrum information obtained by the analysis unit, the inference information obtained by the inference unit, and the basis information obtained by the basis estimation unit.

Control Method for Information Processing Apparatus

A control method for an information processing apparatus according to an embodiment of the present invention is described below. The control method according to this embodiment include at least the following steps.
(1) An information acquisition step for acquiring quantitative information of a test substance estimated by inputting spectrum information of a sample containing the test substance into a learning model.
(2) A degree-of-contribution acquisition step for acquiring the degree of contribution of the acquired quantitative information of the test substance.

In this method, the information processing apparatus is the same as that described above.

### EXAMPLE 1

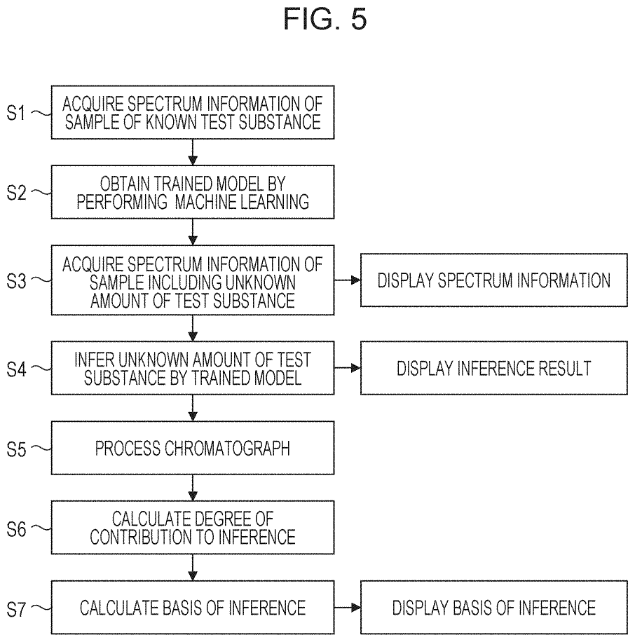

In this example, an explanation is given as to a method for quantifying a test substance in a liquid sample by using, as the analysis unit, high performance liquid chromatography (hereinafter referred to as HPLC). FIG. 5 is a flowchart for explaining the present example.

As a preliminary preparation, a trained model is prepared. First, a plurality of samples each containing a known amount of a test substance are prepared, and spectrum information (chromatography) is obtained by HPLC (step S1). Using the obtained spectrum information and the amount of the test substance as training data, machine learning is performed (step S2). As a specific learning method, a generally used machine learning method such as a neural network or a support vector machine may be used, or a deep learning method having a plurality of hidden layers such as a DNN (deep neural network) or CNN (convolutional neural network) or the like may be used. In a case where there are a plurality of types of test substances, a trained model may be constructed for each type of substance. In a case where the deep learning is used, it is desirable to construct a recurrent neural network.

Next, a value of the unknown amount of the test substance is inferred. A chromatograph of the sample containing the test substance whose amount is unknown is obtained by HPLC (S3). The chromatograph is displayed on the display unit. The chromatograph of the sample is input to the trained model, and the amount of the test substance is inferred (S4). The inference result is displayed on the display.

Furthermore, the basis for the inference of the result is estimated. The chromatograph is data of the intensity i of a signal output from the detector as a function of time, and can be represented by an array of i(t). Here, t is an integer starting from 0. In a case where data is acquired at intervals of Δt, t can be obtained by dividing a data acquisition time by Δt. When an acquisition end time of the chromatograph is denoted as t_{END}Δt, t takes a value from 0 to t_{END}. A new chromatogram j(t) is generated such that j(t)=0 when t=n and j(t)=i(t) when t≠n (S5). Inference is performed by applying the trained model to j(t). Let k(n) denote the absolute value of the difference between the inference result of i(t) and the inference result of j(t), and an array of k(n) is obtained by changing n from 0 to t_{END}. Note that k(n) obtained here represents the degree of contribution of the chromatogram to the inference (S6). The maximum value of the degree of contribution is determined, and the obtained maximum value is displayed on the display unit as the basis for the inference (S7). Two or three of the largest maximum values of the degree of contribution may be selected as the bases for the inference.

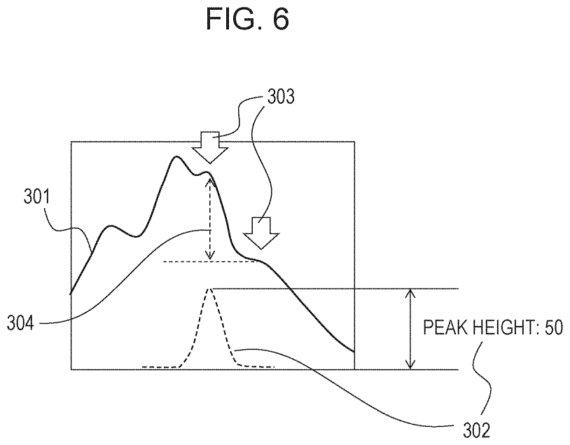

FIG. 6 shows an example of a displaying manner on the display unit. In this example, the test substance is not completely separated from impurities by HPLC, but the peak height (302) which would be obtained if the test substance is isolated is inferred by the machine learning. As bases for inferring this peak height, two points (303) in the chromatogram are pointed to. When the peak Neigh from a baseline is calculated from information on these two points using a conventional method of estimating the peak height, the result (304) is in good agreement with the result inferred using the trained model as can be seen in FIG. 6.

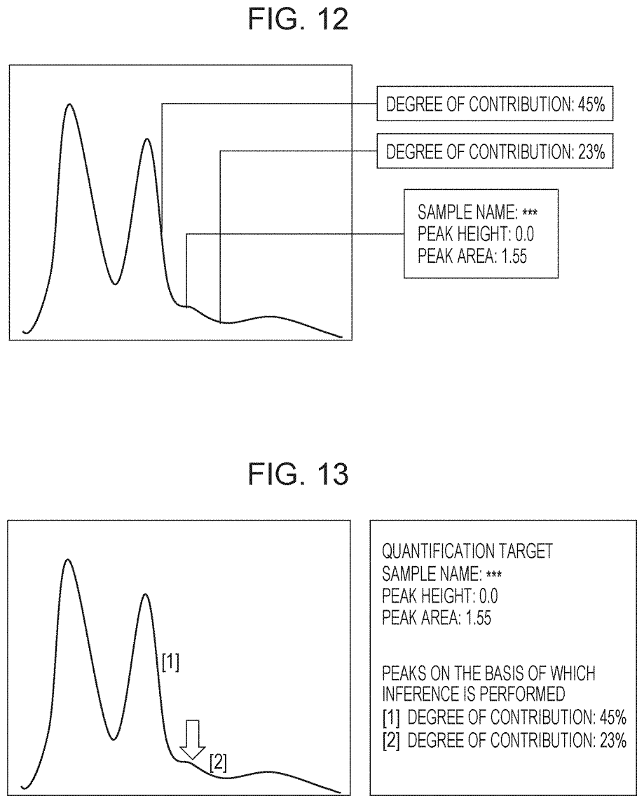

FIG. 11 shows another example of a displaying manner on the display unit. In addition to the measured chromatogram (801) and the inferred peak information (807), a shading gradation is displayed in the chromatogram (801) as the basis for the inference. The darker the part, the greater the degree of contribution. In this example, it is inferred that the substance of interest is not detected (the peak height is 0). A peak would appear at a position 803 of the chromatogram. Actually, the chromatogram has a value denoted by 804 at this position 804 but there is no peak here. The value denoted by 804 appears as a result of being influenced by peaks 805 and 806. 802 indicates another example of a displaying manner, in which the degree of contribution is displayed in a graph instead of the shading gradation 801. FIGS. 12 and 13 show another two examples in which the degree of contribution shown in FIG. 11 is displayed in different manners. In FIG. 12, numerical values of the degree of contribution and corresponding peaks are connected by lines. In FIG. 13, numerical values indicating positions of peaks and corresponding numerical values of the degree of contribution are indicated.

### EXAMPLE 2

The estimation of the basis for the result of the inference in EXAMPLE 1 is changed as follows.

Let i_{MAX} denote a maximum value in the chromatogram. A new chromatogram j(t) is generated such that j(t)=i(t)+iₘₐₓ×0.1 when t=n, and j(t)=i(t) when t≠n. The others are the same as in EXAMPLE 1.

In EXAMPLE 1, a change is detected in a value of the inference result that occurs when a part of the chromatogram is set to 0. In contrast, in this example, a change in the inference result is detected that occurs when a constant is added to a part of the chromatogram. In EXAMPLE 1, there is possibility that the degree of contribution changes depending on the strength of a signal output from the detector, but in EXAMPLE 2, the degree of contribution can be obtained with high accuracy even when the strength of the signal output from the detector is small.

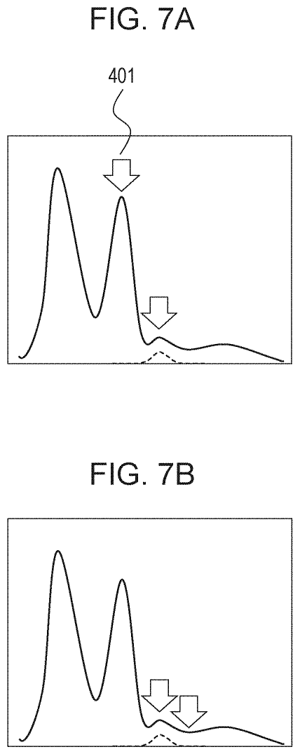

FIG. 7 shows examples of manners of displaying a basis for the inference when the strength of the signal output from the detector is low. The largest two maximum values of the degree of contribution are displayed as the bases for the inference. FIG. 7A corresponds to EXAMPLE 1, and FIG. 7B corresponds to EXAMPLE 2. In FIG. 7A, peak 401 having a large value is selected as the basis although the degree of contribution of the peak 401 is regarded as small because of a low detection sensitivity for the test substance. In FIG. 7B, a peak having a large degree of contribution is correctly selected.

### EXAMPLE 3

In this EXAMPLE 3, an explanation is give as to a method for classifying a test substance in a solid sample using a time-of-flight secondary ion mass spectrometry (hereinafter referred to as TOFSIMS) as the analysis unit. The procedure is described below using the same flowchart as that shown in FIG. 5 used in the explanation of EXAMPLE 1.

As a preliminary preparation, a trained model is prepared. First, a plurality of samples of test substance whose types are known are prepared, mixed with impurities and solidified, and then spectrum information (a mass spectrum) thereof is obtained by TOF-SIMS (step S1). Machine learning is performed using the obtained spectrum information and the types of the test substances as training data (step S2). As a specific learning method, a generally used machine learning method such as a neural network or a support vector machine may be used, or a deep learning method having a plurality of hidden layers such as a DNN (deep neural network) or CNN (convolutional neural network) or the like may be used. In a case where there are a plurality of types of test substances, a trained model may be constructed for each type of substance. When deep learning is used, it is desirable to construct a classification neural network.

Next, for a test substance whose type is unknown, the type is inferred. A mass spectrum of a sample containing the test substance whose type is unknown is obtained by TOF-SIMS (S3). The obtained mass spectrum is displayed on the display unit. The mass spectrum of the sample is input to the trained model thereby inferring the type of the test substance (S4). The inference result is displayed on the display.

Furthermore, the basis for the inference of the result is estimated. The mass spectrum is data of the intensity i of a signal output by the detector as a function of a value obtained by dividing the mass by the electric charge, and can be represented by an array of i(t). Here, t is an integer starting from 0, and data is acquired at intervals of Δt, wherein Δ is determined by a resolution of the device. Thus, t can be obtained such that the mass divided by electric charge is further divided by Δt. When the mass spectrum acquisition end value is denoted by t_{END}Δt, t takes values from 0 to t_{END}. A new chromatogram j(t) is generated such that j(t)=0 when t=n and j(t)=i(t) when t≠n (S5). Inference is performed by applying the trained model to j(t). Let k(n) denote the absolute value of the difference between the inference result of i(t) and the inference result of j(t), and an array of k(n) is obtained by changing n from 0 to t_{END}. Note that k(n) obtained here represents the degree of contribution of the mass spectrum to the inference (S6). The maximum value of the degree of contribution is determined, and the obtained maximum value is displayed on the display unit as the basis for the inference (S7). Two or three of the largest maximum values of the degree of contribution may be selected as the bases for the inference.

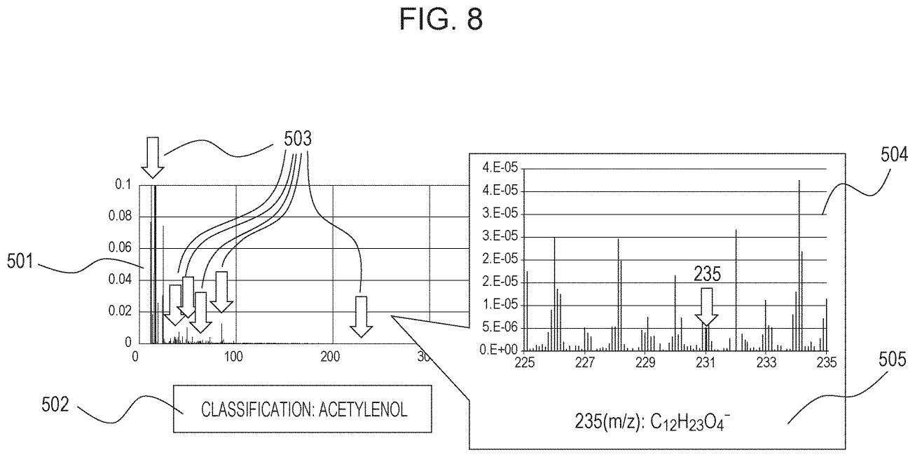

FIG. 8 shows an example of a displaying manner on the display unit. In this example, an additive is identified which is contained in an ultraviolet curable resin containing methyl methacrylate as a main component. 501 indicates the mass spectrum, and 502 indicates a result of identification using the deep learning. It is shown that the additive is identified as acetylenol E-100 (manufactured by Kawaken Fine Chemical Co., Ltd.) from a plurality of additive candidates. 503 indicates the basis for this classification result. 504 indicates an enlarged display of a part selected from the basis 503 by a user. 505 indicates information displayed on the mass spectrum selected as the basis.

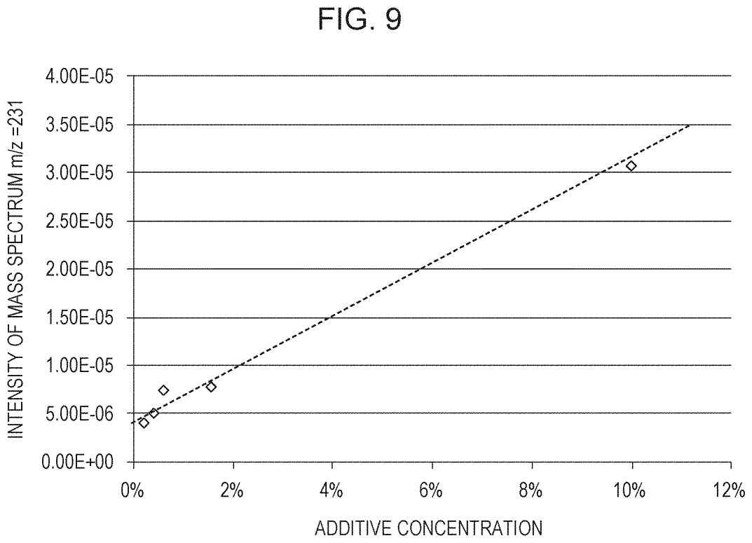

A discussion is given below focusing on the mass spectrum 504 shown as the basis. FIG. 9 shows a mass spectrum m/z=231 obtained when the concentration of the additive (acetylenol E-100) is changed to 0.2%, 0.4%, 0.6%, 1.5%, and 10%. Although m/z=231 is small as a signal, it has a high correlation with the additive concentration, and thus this signal can be regarded as a signal derived from the additive. Therefore, it can be said that the mass spectrum m/z=231 is one of the bases for the identification.

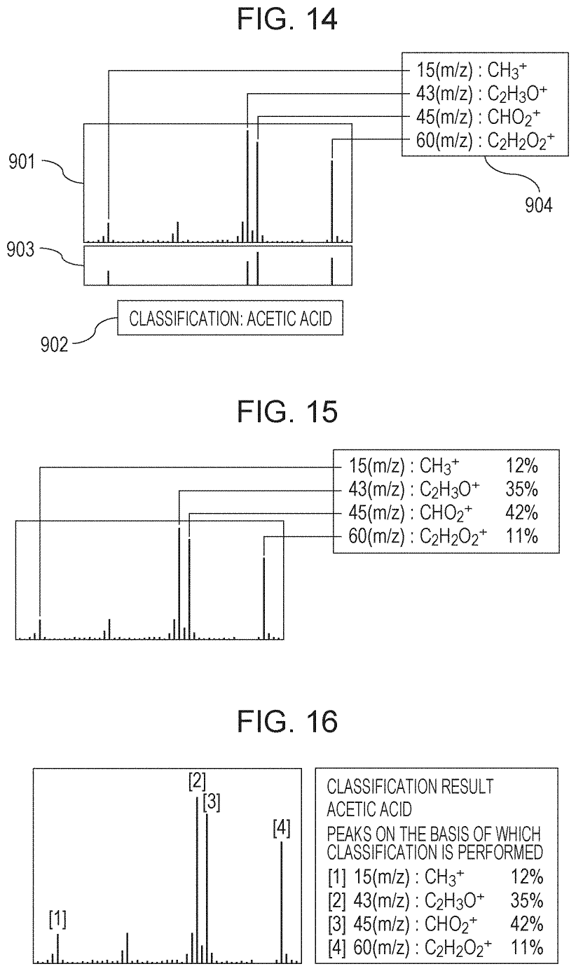

FIG. 14 shows another example of a manner of displaying on the display unit. 901 denotes a mass spectrum, and 902 denotes a result of identification using the deep learning. The degree of contribution in the identification is displayed in 903. 904 denotes information on the mass spectrum having large degrees of contribution. FIGS. 15 and 16 show another two examples in which the degree of contribution shown in FIG. 14 is displayed in different manners. In these examples, information on mass spectrum with large degrees of contribution is displayed together with the values of the degree of contribution thereof. In FIG. 15, information on mass spectrum and a numerical value of the degree of contribution are together connected to a corresponding peak by a line. In FIG. 16, a numerical value indicating the position of a peak is displayed together with corresponding information on a mass spectrum and a numerical value of degree of contribution.

### EXAMPLE 4

The estimation of the basis for the result of the inference in EXAMPLE 3 is changed as follows.

Let i_{MAX} denote a maximum value in the mass spectrum. A new mass spectrum j(t) is generated such that j(t)=i(t)+iₘₐₓ×0.1 when t=n, and j(t)=i(t) when t≠n.

Others are the same as in EXAMPLE 3. In this EXAMPLE 4, the basis for the inference is displayed in a similar manner to EXAMPLE 3.

### EXAMPLE 5

The estimation of the basis for the result of the inference in EXAMPLE 3 is changed as follows.

A new mass spectrum j(t) is generated such that j(t)=0 when t=n1 or t=n2, and j(t)=i(t) when t≠n1 and t≠n2. Let k(n1, n2) denote the absolute value of the difference between the inference result of i(t) and the inference result of j(t), and an array of k(n1, n2) is obtained by changing n1 from 0 to t_{END} and n2 from 0 to t_{END}.

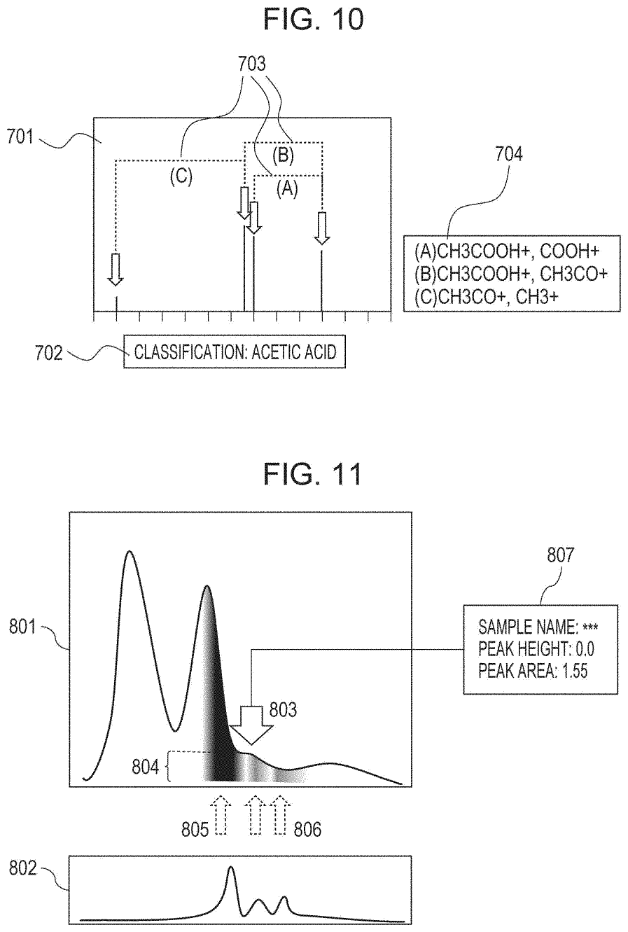

In this case, basis for the inference is given by n1 and n2 at which k (n1, n2) has a maximum value. FIG. 10 shows an example of a displaying manner on the display unit. From the fact that the identification result is obtained based on both n1 and n2 together, it is highly possible that the two existed in close to each other. In FIG. 10, 703(A) suggests that a substance with a peak on the right side, which has a larger mass, was decomposed into a substance with a peak on the left side. A combination of these information can be used as a basis for the inference result.

### EXAMPLE 6

In EXAMPLE 6, a method of simultaneously identifying and quantifying a test substance in a solid sample using a mass spectrometry as the analysis unit is described. The procedure is described below using the same flowchart as that (shown in FIG. 5) used in the explanation of EXAMPLE 1.

As a preliminary preparation, in addition to the learning for different types of test substances performed in EXAMPLE 3, learning is also performed for different amounts of test substances by the same method. In this case, spectrum information and the amounts of the test substances are used as the training data. The basis for the inference can be obtained by the same method as in EXAMPLE 3.

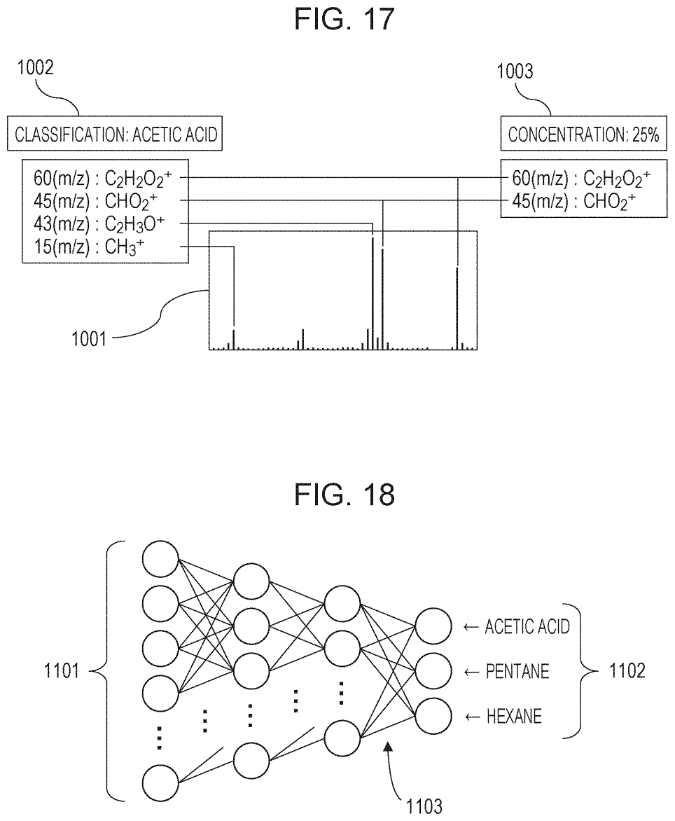

By using both the learning model generated in EXAMPLE 3 and the learning model generated in this EXAMPLE 6, it is possible to infer the type and the amount from one mass spectrum. The spectrum information, the types and the amounts of the test substances may be used as training data, and the type and the amount may be obtained by performing inference once. FIG. 17 shows an example of a displaying manner. 1001 indicates a mass spectrum, and 1002 indicates an inference result of the type and information on a mass spectrum selected as a basis for classifying the type. 1003 indicates an inference result of the amount and information on the mass spectrum selected as the basis for the inference.

### EXAMPLE 7

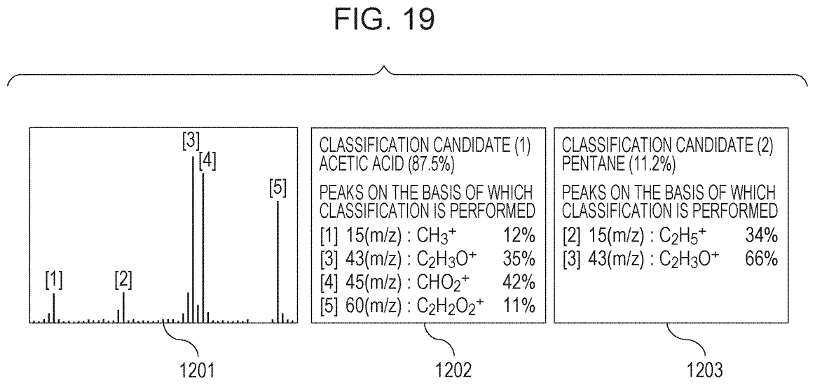

In EXAMPLE 7, a description is given as to another method of identifying a test substance in a solid sample using the analysis unit using the mass spectrometry method. The procedure is described below using the same flowchart as that (shown in FIG. 5) used in the explanation of EXAMPLE 1. As a preliminary preparation, learning is performed for different types of test substances by the same method as in EXAMPLE 3. In the learning, the deep neural network (hereinafter referred to as DNN) shown in FIG. 18 is used. This DNN is of a classification type in which an output layer 1102 has as many nodes as the number of classifications, and the probability for the classification to be correct is output to each node. The training data is given as probability information such that when spectrum information is input, 1 is output in a case where a classification correctly corresponding to the input, and 0 is output in the other cases. It is desirable to use a softmax function as an activation function that connects the output layer and a layer immediately before the output layer. This makes it possible to set output values at nodes of the output layer such that the sum of the output values becomes equal to 1. When spectrum information is input to the input layer of the learning model which has been trained, the probability for each classification is output from the output layer. Here, for one node of the output layer, the basis is estimated in a similar manner as in EXAMPLE 3. By doing the estimation for all nodes of the output layers, it is possible to obtain the basis for each classification result (the degree of contribution of a mass spectrum). FIG. 19 shows an example of a manner of displaying an output result according to EXAMPLE 7. 1201 indicates an input mass spectrum, and 1202 indicates information on a substance for which the highest probability is obtained in the classification result, peak information which is the basis for the classification result, and the degree of contribution. 1203 indicates information on a substance for which the second highest probability is obtained in the classification result, peak information which is the basis for the classification result, and the degree of contribution.

### EXAMPLE 8

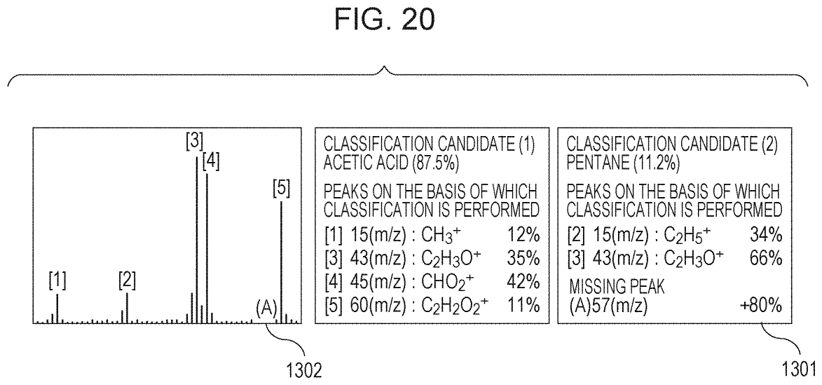

A mass spectrum is classified in a similar manner as in EXAMPLE 7, and information on a substance, peak information on the basis of which the classification is made, and a degree of contribution are displayed for each classification candidate. A maximum value in the spectrum information is denoted by i_{MAX}, and a new mass spectrum j(t) is generated such that j(t)=i(t)+iₘₐₓ when t=n and j(t)=i(t) when t≠n. The others are the same as in EXAMPLE 3, and a degree of contribution is newly determined for each classification candidate. The degree of contribution determined here indicates an amount of increase in the probability for classification to be correct that occurs when a peak is added to a part of the mass spectrum for each classification candidate. FIG. 20 shows an example of an output result displayed according to the present embodiment. A missing peak indicated in 1301 is a peak which has a greatest degree of contribution to increase the probability for classification to be correct. In the example shown in FIG. 20, if a peak exists at (A) (m/z=57, denoted by 1302 in FIG. 20), the probability will increase by 80% that the classification candidate (2), that is, pentane, is a correct classification. That is, this mass spectrum is classified such that the probability that classification candidate (1), that is, acetic acid, is correct is 87.5%, but if there is a peak at (A), the probability for the classification candidate (2) to be correct will become higher than that for the classification candidate (1), and the substance will be classified as pentane. It can be said that the fact that there is no peak at (A) causes the probability of the classification candidate (1) to be highest.

The information processing apparatus according to the present invention is capable of performing spectrum analysis, which used to require knowledge and technology, using deep learning and displaying a result of the spectrum analysis together with a basis on which the result is inferred thereby making possible to determine whether the obtained result is reliable.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. An information processing apparatus comprising:
information acquisition means configured to acquire quantitative information on a test substance, which is estimated by inputting spectrum information of a sample including the test substance into a learning model; and
degree-of-contribution acquisition means configured to acquire a degree of contribution of the acquired quantitative information on the test substance.

2. The information processing apparatus according to claim 1, wherein the degree of contribution is information regarding a degree of contribution of information included in the spectrum information in acquiring quantitative information on the test substance.

3. The information processing apparatus according to claim 1, wherein the spectrum information includes information regarding a graph having the plurality of peaks, wherein heights of the peaks correspond to the quantitative information on the substance included in the sample and positions of the peaks correspond to types of substances included in the sample.

4. The information processing apparatus according to claim 3, wherein the degree of contribution is information indicating a degree of contribution of each of the plurality of peaks in acquiring quantitative information on the test substance.

5. The information processing apparatus according to claim 1, wherein the degree-of-contribution acquisition means acquires the degree of contribution based on a degree of influence to quantitative information on the test substance acquired when the spectrum information of the sample is changed.

6. The information processing apparatus according to claim 5, further comprising display control means configured to perform control such that the acquired degree of contribution is displayed on a display unit.

7. The information processing apparatus according to claim 6, wherein the display control means further performs control such that the acquired quantitative information on the test substance is displayed on the display unit.

8. The information processing apparatus according to claim 1, wherein the learning model is a trained model which has been trained using, as training data, a plurality of sets of spectrum information for training generated based on spectrum information of the test substance and quantitative information on the test substance identified based on the spectrum information of the test substance.

9. The information processing apparatus according to claim 8, wherein the spectrum information for training is generated using the spectrum information of the test substance and random noise.

10. The information processing apparatus according to claim 9, wherein the random noise has a waveform obtained by combining a plurality of Gaussian functions.

11. The information processing apparatus according to claim 1, further comprising estimation means configured to estimate quantitative information on the test substance by inputting spectrum information of the sample into the learning model.

12. The information processing apparatus according to claim 1, wherein the spectrum information is at least one of a chromatogram, a photoelectron spectrum, an infrared absorption spectrum, a nuclear magnetic resonance spectrum, a fluorescence spectrum, a fluorescent X-ray spectrum, an ultraviolet/visible absorption spectrum, a Raman spectrum, an atomic absorption spectrum, a flame emission spectrum, an emission spectrum, an X-ray absorption spectrum, an X-ray diffraction spectrum, a normal magnetic resonance absorption spectrum, an electron spin resonance spectrum, a mass spectrum, and a thermal analysis spectrum.

13. The information processing apparatus according to claim 1, further comprising analysis means for performing analysis for acquiring spectrum information of the sample.

14. The information processing apparatus according to claim 13, wherein the analytical means performs at least one of chromatography, capillary electrophoresis, photoelectron spectroscopy, infrared absorption spectroscopy, nuclear magnetic resonance spectroscopy, fluorescence spectroscopy, fluorescent X-ray spectroscopy, visible/ultraviolet absorption spectroscopy, Raman spectroscopy, atomic absorption spectroscopy, flame emission spectroscopy, emission spectroscopy, X-ray absorption spectroscopy, X-ray diffraction spectroscopy, electron spin resonance spectroscopy using normal magnetic resonance absorption, mass spectroscopy, and thermal spectroscopy.

15. The information processing apparatus according to claim 14, wherein the analysis means performs time-of-flight secondary ion mass spectrometry.

16. The information processing apparatus according to claim 1, wherein the test substance is at least one of a protein, DNA, a virus, a fungus, a water-soluble vitamin, a fat-soluble vitamin, an organic acid, a fatty acid, an amino acid, a sugar, a pesticide, and an environmental hormone.

17. The information processing apparatus according to claim 1, wherein the quantitative information is at least one of information indicating an amount of the test substance included in the sample, information indicating a concentration of the test substance included in the sample, information indicating whether or not the test substance exists in the sample, information indicating a ratio of a concentration or an amount of the test substance included in the sample with respect to a reference amount of the test substance, and information indicating a ratio of an amount or a concentration of the test substance included in the sample.

18. A control method for an information processing apparatus, comprising:
an information acquisition step for acquiring quantitative information on a test substance, which is estimated by inputting spectrum information of a sample including the test substance into a learning model; and
a degree-of-contribution acquisition step for acquiring a degree of contribution of the acquired quantitative information on the test substance.
